(19) United States
(12) Patent Application Publication
(10) Pub. No.: US 2024/0273820 A1
(43) Pub. Date: Aug. 15, 2024

(54) SYSTEM AND METHOD FOR THREE-DIMENSIONAL MODELING BASED ON A TWO-DIMENSIONAL IMAGE

(71) Applicant: Expanse Plans, LLC, Houston, TX (US)

(72) Inventors: Donn Lamoureux, Wimberley, TX (US); Pamela Lamoureux, Wimberley, TX (US); Alex Lamoureux, Wimberley, TX (US); Eric Lamoureux, Wimberley, TX (US); Richard Belote, Houston, TX (US)

(21) Appl. No.: 18/439,150

(22) Filed: Feb. 12, 2024

Related U.S. Application Data
(60) Provisional application No. 63/484,319, filed on Feb. 10, 2023.

(51) Int. Cl. G06T 17/00; G06F 30/13; G06T 7/11; G06T 7/73; G06V 10/26; G06V 10/30; G06V 10/40; G06V 30/413; G06V 30/422

(52) U.S. Cl. CPC G06T 17/00; G06F 30/13; G06T 7/11; G06T 7/73; G06V 10/26; G06V 10/30; G06V 10/40; G06V 30/413; G06V 30/422; G06T 2200/24; G06T 2207/20061; G06T 2207/30176; G06T 2210/04

(57) ABSTRACT

Disclosed are a system and method for generating and viewing a 3D file from a 2D architectural floorplan. The method includes the steps of: uploading a 2D file of an architectural floorplan; inputting default structural settings corresponding to structural features of the architectural floorplan; executing a symbol detection model on the 2D file so as to detect symbols present in architectural floorplan; executing a segmentation model on the 2D file so as to identify segments corresponding to walls and windows; vectorizing the identified segments resulting from the execution of the segmentation model; and generating a 3D file based on the results of the symbol detection model and the segmentation model. The resulting 3D file is viewable in a 3D computer graphics engine. The system includes a frontend adapted to receive the 2D architectural floorplan file, and a backend adapted to enqueue worker instances including the segmentation and symbol detection models.

### CROSS-REFERENCE TO RELATED APPLICATIONS

The present application claims priority to U.S. Provisional Application No. 63/484,319, filed on Feb. 10, 2023.

### FIELD OF THE INVENTION

The present invention relates to the field of three-dimensional (3D) multimedia and has certain specific applications to experiential media. More particularly, the present invention relates to the conversion of a two-dimensional (2D) image into a 3D model. Even more particularly, the present invention relates to the conversion of a 2D floor plan document or photo into a 3D model.

### BACKGROUND OF THE INVENTION

At The creation of 3D models and interactive 3D experiences requires knowledge and time that very few people possess. Often, years of education beforehand and weeks or months of work are required during the process of creating such digital assets. Additionally, specialized software may be required which can be prohibitively expensive.

3D models are utilized in many areas and can be used in augmented and virtual reality applications, which enable a user to virtually navigate within a three-dimensional space. As can be appreciated, this can be useful in several applications including video games, “metaverse” experiences, and training applications for military and other organizations. 3D modeling and interactive 3D experiences are also useful in real estate.

Floor plans are 2D images which illustrate the structural and nonstructural components of a building such as a home or a commercial real estate space. Floor plans are used by real estate—1—professionals to market a building or space to a tenant or buyer. Oftentimes, it can be difficult for the tenant or buyer to visualize the three-dimensional space based only upon a two-dimensional floor plan. Further, it can be difficult for the tenant or buyer to visualize the space with their desired furnishings.

As such, real estate professionals can expend much time and effort in attempting to develop 3D models to help market their properties. One manner of creating such a model includes taking a plurality of panoramic photographs and using a software to create a “virtual tour”. While this method is certainly useful, there are number of drawbacks, including the fact that the space cannot easily be customized to include furniture or alternate nonstructural component locations for the space. For example, the build out of a commercial space may include the relocation of certain nonstructural elements, including interior walls, doors and fixtures.

Another method of creating a 3D model involves the use of specialized software to draw the components of the 3D space based upon the 2D floorplan. This requires a great amount of time and energy, particularly when the real estate professional may wish to market more than one space to a prospective tenant or buyer. In most cases, the real estate professional would need to hire a specialized person or firm to create the 3D model.

In addition to commercial real estate, various industries use such 3D modeling, including: education, medical, oil and gas, industrial technology, civil engineering and entertainment industries.

It is therefore an object of the present invention to provide a system and method for generating a 3D model based on a two-dimensional floorplan or image.

It is another object of the present invention to provide a system and method for 3D modeling which can be used in virtual and augmented reality applications and other immersive 3D experiences.

It is another object of the present invention to provide a system and method for 3D modeling which populates the 3D model with objects such as chairs, tables, and nonstructural components.

It is a further object of the present invention to provide a system and method for 3D modeling based upon 2D images which can be used by lay persons.

It is another object of the present invention to provide a system and method for 3D modeling based upon 2D images which is both fast and relatively inexpensive to use.

It is another object of the present invention to provide a system and method for generating a 3D image file based upon a 2D .png, .jpeg or .pdf file.

It is another object of the present invention provide a system and method for 3D modeling which generates .gltf, .obj, .fbx, and .stl files.

It is another object of the present invention to provide a system and method for 3D modeling that utilizes machine learning and artificial intelligence.

These and other objects and advantages of the present invention will become apparent from a reading of the attached specification.

### SUMMARY OF THE INVENTION

The present invention is a method for generating a three-dimensional (3D) file from a two-dimensional (2D) architectural floorplan including the steps of: uploading a 2D file of an architectural floorplan; inputting default structural settings corresponding to structural features of the architectural floorplan; executing a symbol detection model on the 2D file so as to detect symbols present in architectural floorplan; executing a segmentation model on the 2D file so as to identify segments in the 2D file corresponding to walls and windows; vectorizing the identified segments resulting from the execution of the segmentation model; and generating a 3D file based on the results of the symbol detection model and the segmentation model, wherein structural features identified in the segmentation model are extruded in the vertical direction based on the inputted default structural settings, and wherein detected symbols resulting from the symbol detection model are placed in space in the 3D file.

In an embodiment, the step of generating a 3D file may be executed utilizing Blender 3D computer graphics software tool set.

In an embodiment, the generated 3D file may be viewed utilizing Unreal Engine.

In an embodiment, the detected symbols are preferably masked prior to execution of the segmentation model.

In an embodiment, the method further includes the step of: masking the detected symbols and identified segments; and Identifying millwork present in the architectural floorplan.

In an embodiment, after the step of identifying millwork, the method may further include the step of: identifying mullion present in the architectural floorplan.

In an embodiment, after the step of executing a symbol detection model, the method may further include the step of: post-processing of identified symbols so as to identify location and type of doors and columns present in the architectural floorplan, wherein the symbols are post-processed based on standard heuristics for architectural floorplans.

In an embodiment, the segmentation model has been trained to identify types of segments present in floorplans.

In an embodiment, before the step of executing a symbol detection model, the method may further include the step of: preprocessing the 2D file for denoising, thresholding and isolation of the floorplan portion of the 2D file and removal of extraneous text and figures.

In an embodiment, the 2D file is saved to a cloud storage service.

In an embodiment, a database file is generated based on the uploaded 2D file and the inputted default structural settings.

In an embodiment, the method may further include the steps of: inputting default finish settings; and applying finishes to the 3D file based on the inputted default finish settings.

In an embodiment, the method may further include the step of: converting the uploaded 2D file to PDF format.

In an embodiment, the step of post-processing of identified symbols includes utilizing the circle Hough Transform to provide details on circular columns and doors present in the architectural floorplan.

The present invention is also a system for generating a three-dimensional (3D) file based on a two-dimensional (2D) architectural floorplan. The system may include: a frontend having a graphical user interface, the frontend adapted to receive a 2D image of an architectural floorplan; a cloud storage service in communication with the frontend; and a backend in communication with the frontend and with the cloud storage device, the backend adapted to enqueue a plurality of worker instances. The plurality of worker instances may include: a symbol detection model trained to detect symbols present in architectural floorplans; a segmentation model trained to identify segments present in architectural floorplans; and a Blender software adapted to transform 2D outputs from the symbol detection model and segmentation model into a 3D file based on structural settings contained in a database file.

In an embodiment, the frontend is in communication with a 3D computer graphics engine, such that the 3D file can be viewed.

In an embodiment, the graphical user interface of the frontend is adapted to receive the structural settings.

In an embodiment, the plurality of worker instances further include: a vectorization worker instance wherein the identified segments are vectorized.

In an embodiment, the plurality of worker instances further include: a millwork detection worker instance, wherein detected symbols and identified segments are masked to yield millwork.

In an embodiment, the graphical user interface of the frontend is adapted to receive finish settings, wherein the finish settings are utilized by the Blender software to apply finishes to the 3D file.

This foregoing Section is intended to describe, with particularity, the preferred embodiments of the present invention. It is understood that modifications to this preferred embodiment can be made within the scope of the present claims. As such, this Section should not to be construed, in any way, as limiting of the broad scope of the present invention. The present invention should only be limited by the following claims and their legal equivalents.

### BRIEF DESCRIPTION OF DRAWINGS

FIG. 1 illustrates a sample 2D image or floor plan which will be transformed using the software of the present invention into a 3D image file.

FIG. 2 illustrates the web or mobile application which utilizes the system and method of the present invention.

FIG. 3 illustrates the image file resulting from the segmentation and symbol detection models of the present invention.

FIG. 3A an enlarged view of a portion of FIG. 3.

FIG. 4 illustrates the results of the step of post-processing of doors.

FIG. 4A an enlarged view of a portion of FIG. 4.

FIG. 5 illustrates the results of the step of post-processing of columns.

FIG. 6 illustrates the step of millwork detection.

FIG. 7 illustrates the step of mullion detection.

FIG. 8 illustrates an overview of the system and method of the present invention.

FIG. 9 illustrates a 3D output generated based on the 2D image.

### DETAILED DESCRIPTION OF THE INVENTION

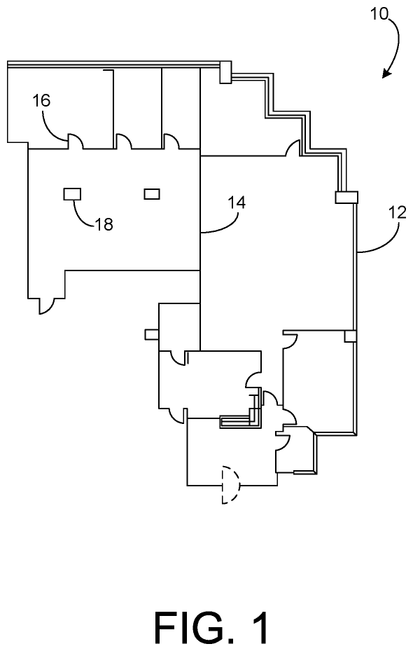

Referring to FIG. 1, there is shown an image of a floorplan 10. This two-dimensional (2D) image can be in the form of a PDF file, or may be a photograph taken by the user of a 2D floorplan. As can be seen in FIG. 1, the floorplan 10 includes the layout of a building, including exterior walls 12 and interior walls 14. Doors and door frames 16 and interior columns 18 are also shown. With the system and method of the present invention, the image of the floorplan 10 is all that is required to quickly and easily create a 3D model based upon the floorplan 10.

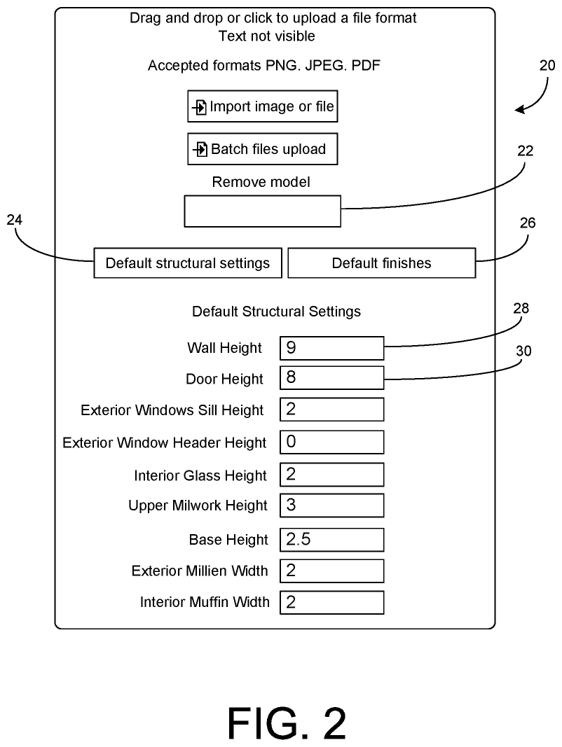

Referring to FIG. 2, there is shown the graphic user interface (GUI) of the mobile or web application 20 of the system of the present invention. The mobile or web application 20 can be on a desktop or mobile device. The floorplan 10 may be inserted by “drag and drop” or can be uploaded by selecting either “Import Image or File” or “Batch Files Upload”. The GUI additionally may have fields 22 for naming the model to be created. The floorplan image is saved to a cloud storage service (or other location), and the upload triggers the creation of a database entry, which contains data on the current processing step, timing reports, the file name, visibility (public or private), and other useful information for managing the model.

FIG. 2 also illustrates that the GUI contains fields for inputting default structural settings and default finishes, 24 and 26, respectively. These inputs include such defaults as wall height 28 and door height 30. As will be explained hereinafter below, the default structural settings 24 aid the present invention in creation of the three-dimensional (3D) model, as the 2D floorplan does not contain this information. Additionally, the default finishes 26 are utilized in the 3D model. The database file stores this information as well.

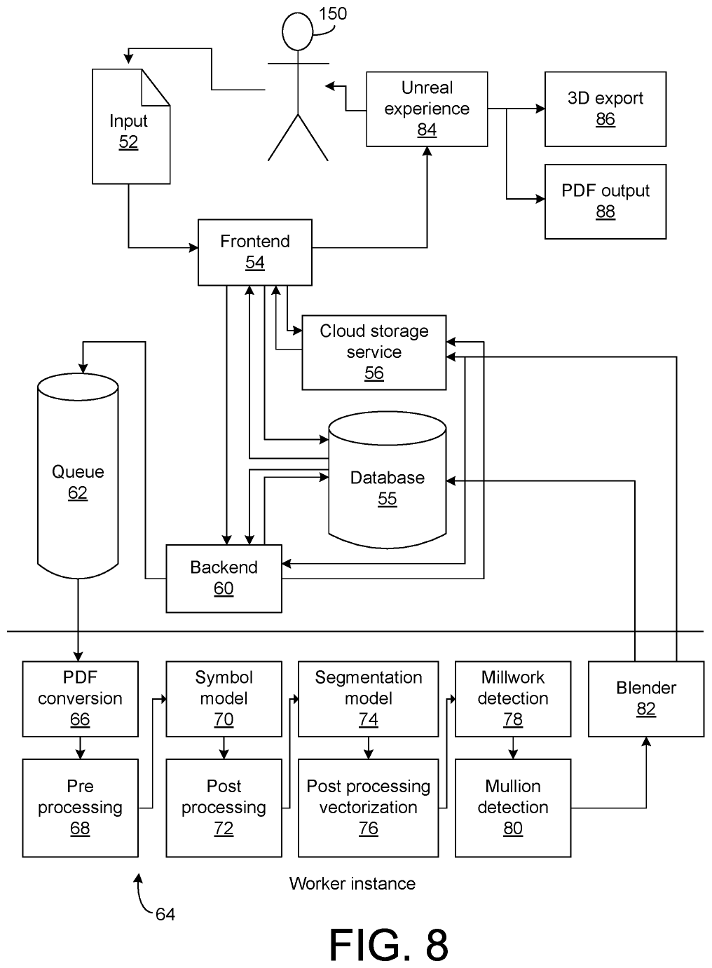

After the 2D floorplan is uploaded, a pre-processing step occurs which is discussed below in reference to FIG. 8).

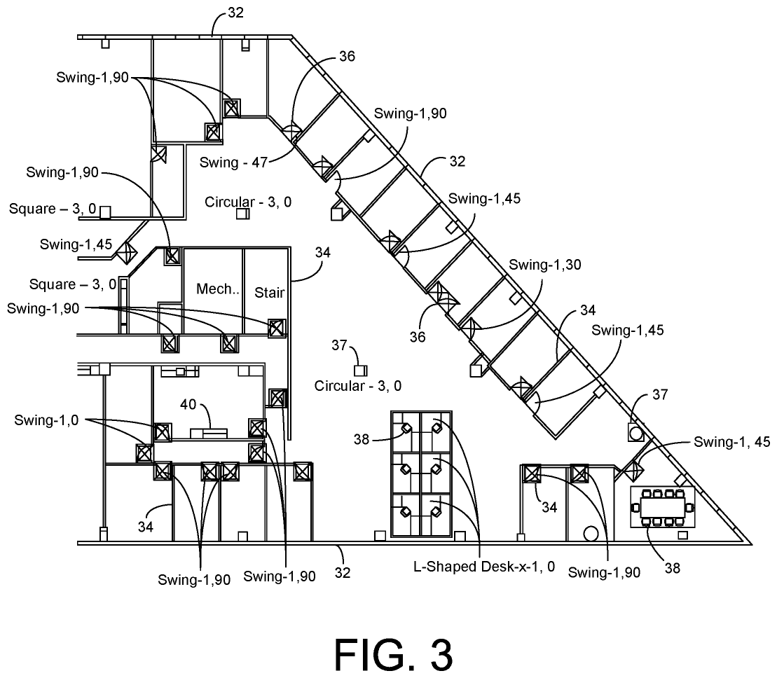

The software then executes a symbol detection model. The resulting file (which also contains the results of a subsequently-executed segmentation model) is shown in FIGS. 3 and 3A. Note that the image shown in FIG. 3 is from a different floorplan than what is illustrated in FIG. 1.

In the present invention, the symbol detection model has been trained to identify types of symbols present in floorplans. Referring to FIGS. 3 and 3A, it can be seen that the symbol detection model has identified doors 36, columns 37 and furniture 38. Millwork 40 (currently unidentified) is also shown in FIG. 3. Specifically, the symbol detection model outputs metadata regarding the position, bounding box, rotation, and type of each detected symbol.

Once the symbol detection models has been executed, post-processing of the symbols occurs. Each type of symbol is post-processed based on standard heuristics for architectural floorplans and the preliminary results are outputted by the symbol detection model.

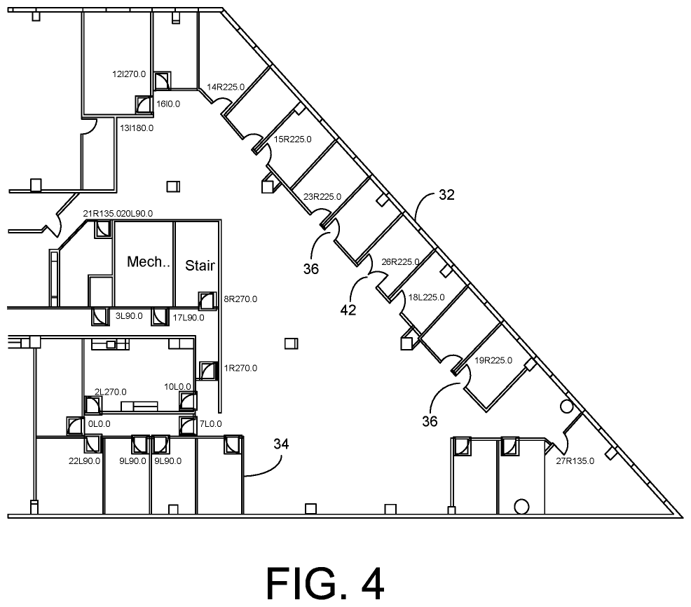

The post-processing step includes the post-processing of columns, resulting in the image shown in FIG. 5. As can be seen in FIG. 5, the columns 37 are now identified by their shape (circular or square in this example). Additional information regarding the columns is also generated in this step and displayed on the resulting image and saved in the database entry.

For circular columns, circle Hough Transforms are used to pinpoint the exact location and radius of the column. For square and rectangular columns, this step finds their contours to pinpoint their bounding box, rotation, and coordinates.

FIGS. 3 and 3A also illustrate bounding boxes for the detected symbols, and in particular the bounding boxes for doors 36, columns 37 and furniture 40. Additionally, it can be seen how FIGS. 3 and 3A illustrate information related to the detected symbols, such as the nature of the column (circular in FIG. 3A) and the type, number and degree of swing of the doors 36.

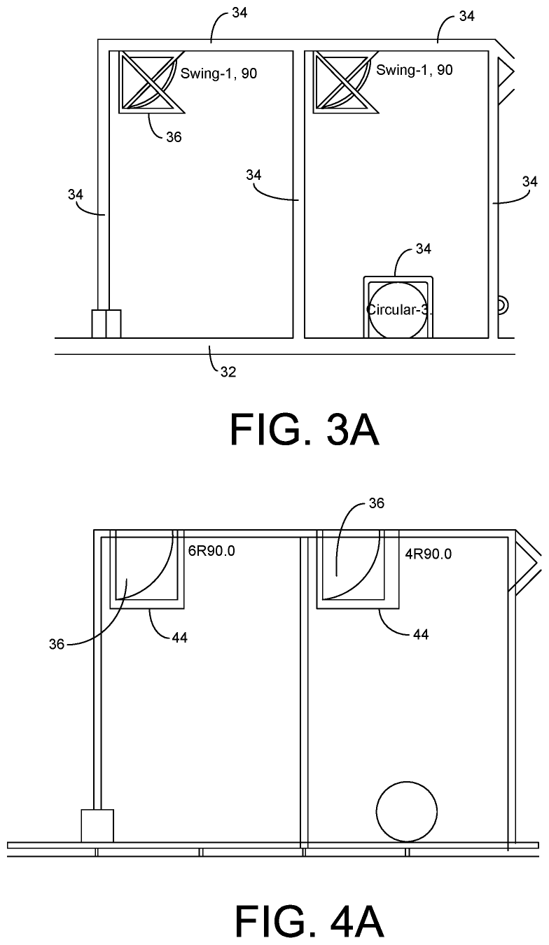

Post-processing of the symbols also includes a door post-processing step, resulting in the image shown in FIG. 4. In this step, the circle Hough Transform is used once more to fit a circle on the detected door. For an exact representation, the algorithm identifies which 90-degree arc contains the circle match, yielding two points (start and end of the arc). One of those points is connected by a line to the center of the circle (which is in the same position as the door's hinge), and that information reveals whether the door is left-handed or right-handed, and consequently yielding the bounding box of that door. Any pair of doors (for example, doors 42 in FIG. 4) that open away from each other, and the two points of the bounding box closest to one another are sufficiently near, are interpreted as double doors, and have their own 3D model.

The post-processing algorithms utilized in the present invention—including contour approximation and mathematical tests—demonstrate novel solutions to refine and validate the detected symbols and segments. By applying geometric analysis and heuristic rules based on architectural standards, these algorithms enhance the accuracy of the generated 3D models while minimizing computational overhead.

FIG. 4A an enlarged view of a portion of FIG. 4. In FIG. 4A, it can be seen how the original bounding box 44 (from the symbol detection model/step) is shown, while a more precise location and visualization of the door 36 (i.e. the final post-processed results) is shown.

By identifying symbols first, the identification of structural elements such as walls can be more easily accomplished due to the ability to mask out the identified items.

A segmentation model is a type of machine learning or computer vision model used for image analysis and object recognition tasks. The goal of segmentation is to partition an image into multiple segments or regions, each corresponding to a particular object or feature of interest. Segmentation models are typically trained on large datasets with annotated images, using techniques such as convolutional neural networks (CNNs), fully convolutional networks (FCNs), and more recently, architectures like U-Net, Mask R-CNN, and DeepLab.

In the present invention, the segmentation model has been trained to identify types of segments present in architectural floorplans. The segmentation model is executed after the symbol detection model and post-processing of the detected symbols. Referring to FIG. 3, it can be seen that the segmentation model has identified exterior walls 32 and interior walls 34. The segmentation model may also identify windows, for example. This information will be used later in the process to extrude in vertical space to illustrate in these segments/features in 3D.

FIG. 3A also shows the output of the segmentation model. In FIG. 3A, it can be seen how the exterior walls 32 and interior walls 34 have been identified and marked/shown using a line type, color or highlight, wherein the line type, color or highlight is different depending on the segment identified. In FIG. 3A, the exterior walls 32 are highlighted with a thicker line than the interior walls 34. However, in the actual application, the different segments are preferably shown with different color lines.

Once segmentation and symbol detection has occurred, the millwork can now be identified. Wall and door trim (i.e. non-structural wood or similar) is generally considered to be millwork. Because all other the items have been identified, the found items (i.e the found/identified geometry from the input image) can be masked from the image. The unmasked items in the image are therefore considered to be millwork.

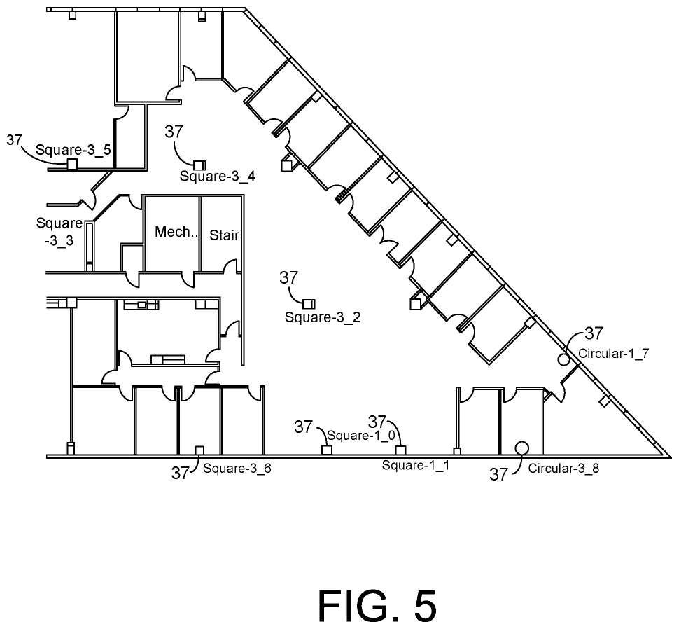

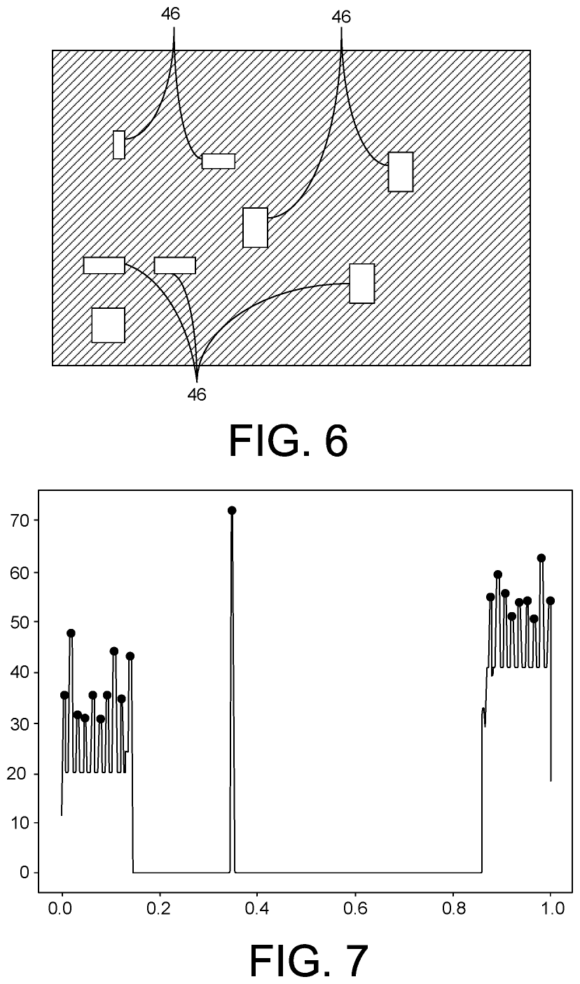

FIG. 6 illustrates such an image, where the masked items/geometries are shown hatched (note: the image is not identical to the previously-shown images, but is a simplified example). The remaining areas (shown as blank/white) are thus identified as millwork 46. The contours and bounding boxes of the millwork are generated in a similar manner to the earlier detected symbols. Solid masking may be used in the actual application, but hatching is shown in FIG. 6 for ease of illustration.

For a complete 3D representation of a physical space, details are important for a realistic depiction. A mullion is a vertical element that forms a division between units of a window. The present invention contains a mullion detection step, which is represented in FIG. 6. This graph has the window parameterization on the X axis and black pixel count inside a Gaussian Blur convolution on the Y axis. The algorithm determines the peaks of black pixel count, which are interpreted as mullions, and converts the parameterization back to exact coordinates on the 2D image.

Specifically, for the exterior mullions, this step analyses the brightness along the exterior window path from the vectorized image, assigning a dynamic threshold, and the peaks of black pixel count. The parameterization is converted to exact coordinates of the mullions (as shown in FIG. 6).

For interior mullions, the algorithm masks out everything but the interior windows, full-height or otherwise, and finds the remaining contours and their centers, which are the locations of those mullions. For both types of mullions, the rotation is parallel to the normal vector of the window path at that point.

Referring to FIG. 8, there is shown an overview of the system and method of the present invention, wherein the final steps are also shown and will be discussed below. In FIG. 8, it can be seen how a user 50 uploads an input file 52 at the frontend 54. The input file 52, as discussed above, can be a PDF or other image file of the floorplan. The frontend 54 contains the GUI discussed above.

The input file 52 and other information (such as default settings) are saved in the cloud storage service (or other storage) 56, and a file is created on the database 58. The backend 60 of the software sets a queue 62.

A plurality of worker instances 64 are shown. These include the steps and models discussed herein above. The queue 62 is consumed by the worker instances 64. Shown first is the PDF conversion 64, which is utilized in the even that the input 52 is a file type other than PDF. The PDF (converted or original) is then subjected to preprocessing 68. In the preprocessing step 68, the 2D image is first submitted to industry-standard denoising and preprocessing procedures, such as thresholding, and the isolation of the floorplan and removal of extraneous text and figures.

Next, the symbol detection model 70 is run, and post-processing steps 72 related to the symbols (doors, for example) are executed, both of which are discussed above.

Thereafter, the segmentation model 74 is run, and a post-processing step 76 related to the segmentation is run. This post-processing involves vectorization of the geometries and aligning the lines representing the centerlines and contour lines, yielding sharp corners and straight lines.

The millwork detection 78 and mullion detection 80 steps are then run, as discussed above. At this point, the required data for the 3D conversion and visualization has been assembled. Each of the previous steps has resulted in files required for the 3D visualization.

Next, Blender 82 is utilized to create the final 3D model. Blender is a free and open-source 3D creation suite. It's a comprehensive tool used for modeling, animation, rendering, compositing, motion tracking, and video editing. In this step, the algorithm developed by the present inventors uses a custom Blender method, and extrudes the vectorized 2D image in the Y (vertical) axis, placing the corresponding geometry type for each line. Then, 3D models of identified symbols (i.e. the columns, doors, millwork, mullions, furniture, and other fixtures) are placed in the exact coordinate and rotation detected in the previous steps.

At the end of the Blender step 82, a GL Transmission Format Binary file (“GLB file”) is generated. All information is uploaded back to the cloud storage service 56. The worker instance 64 finalizes the completion of the task to the message-broker service (queue 62). This is also updated on the database entry 58, making the model viewable on the frontend 54. Optionally, an email can be sent to the user 50 notifying them of the completion of the model.

When the user 50 requests to view a model, it is loaded on a custom Unreal experience 84, along with the texture information and floorplan. That Unreal (viewing) experience 84 dynamically assigns the default texture from the database entry, and makes it possible for the user 50 to edit the structural and visual settings and also to move and/or place objects within the 3D model 86. The viewing experience preferably also has a walkthrough mode, for a first-person view. The system can also export the edited model back to a 3D file, or generate a branded PDF with renderings of the model.

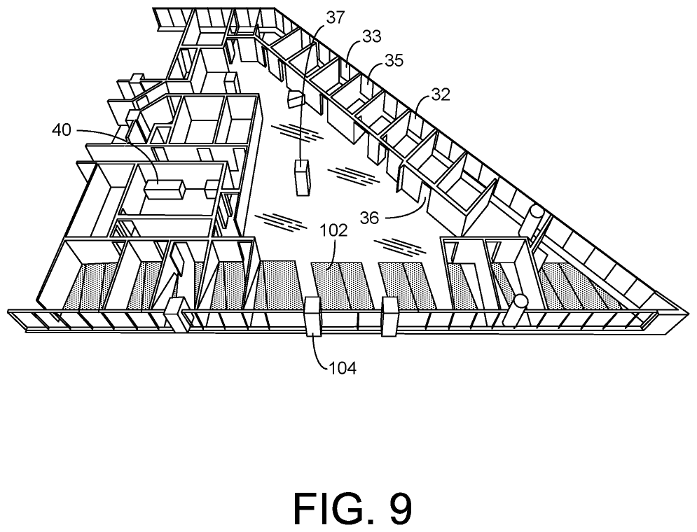

FIG. 9 illustrates a completed 3D model 100 as can be viewed through the Unreal Engine. The 3D model contains all identified geometries, such as exterior walls 32, windows 33, mullion 35 and columns 37. Millwork 40 is also shown, as is sunlight 102 entering the windows 33 along the side 104 of the model, making for an accurate and realistic viewing of the space, based only on the floorplan and default settings (structural and finishes). This allows the user to easily experience and visualize the space.

The system and method of the present invention represents a significant technical improvement over traditional approaches to 3D modeling from 2D floor plans. By utilizing advanced image processing techniques, machine learning algorithms, and 3D modeling software, the system and method of the present invention streamlines the process of converting 2D floor plans into accurate and realistic 3D models. Unlike manual methods or basic computer data manipulation, this approach leverages sophisticated algorithms and software tools to automate and optimize the modeling process.

The system and method of the present invention significantly increases the efficiency of the computing process by automating various steps that would otherwise require manual intervention or complex computations.

For example, the novel masking of identified elements, as described, plays a crucial role in streamlining the segmentation process. By masking out detected symbols and segments, the system focuses the segmentation model's attention on relevant areas of the floor plan, reducing processing time and computational resources.

Additionally, the use of machine learning models for symbol detection and subsequent post-processing improves efficiency by accurately identifying and refining detected symbols without manual intervention. This automated approach minimizes the need for human oversight and accelerates the overall modeling process.

The symbol detection model of the present invention, trained to identify various symbols present in architectural floor plans, represents a novel and inventive application of machine learning in the field of architectural modeling. By leveraging annotated datasets and advanced neural network architectures, this model can accurately detect symbols such as doors, columns, and furniture, contributing to the efficiency and accuracy of the overall system.

The segmentation model of the present invention, trained to identify segments corresponding to walls, windows, and other architectural features, employs innovative techniques in image analysis and object recognition. Through convolutional neural networks and other deep learning approaches, this model partitions the floor plan image into meaningful segments, facilitating the subsequent 3D modeling process.

Overall, the system and method of the present invention represent a significant technical advancement in the field of architectural modeling, offering efficient, automated, and accurate solutions for generating 3D models from 2D floor plans.

1. A method for generating a three-dimensional (3D) file from a two-dimensional (2D) architectural floorplan comprising the steps of:
uploading a 2D file of an architectural floorplan;
inputting default structural settings corresponding to structural features of the architectural floorplan;
executing a symbol detection model on the 2D file so as to detect symbols present in architectural floorplan;
executing a segmentation model on the 2D file so as to identify segments in the 2D file corresponding to walls and windows;
vectorizing the identified segments resulting from the execution of the segmentation model; and
generating a 3D file based on the results of the symbol detection model and the segmentation model, wherein structural features identified in the segmentation model are extruded in the vertical direction based on the inputted default structural settings, and wherein detected symbols resulting from the symbol detection model are placed in space in the 3D file.

2. The method of claim 1, wherein the step of generating a 3D file is executed utilizing Blender 3D computer graphics software tool set.

3. The method of claim 1, wherein the generated 3D file is viewed utilizing Unreal Engine.

4. The method of claim 1, wherein the detected symbols are masked prior to execution of the segmentation model.

5. The method of claim 1, further comprising the step of:
masking the detected symbols and identified segments; and
identifying millwork present in the architectural floorplan.

6. The method of claim 5, after the step of identifying millwork, further comprising the step of:
identifying mullion present in the architectural floorplan.

7. The method of claim 1, after the step of executing a symbol detection model, further comprising the step of:
post-processing of identified symbols so as to identify location and type of doors and columns present in the architectural floorplan, wherein the symbols are post-processed based on standard heuristics for architectural floorplans.

8. The method of claim 1, wherein the segmentation model has been trained to identify types of segments present in floorplans.

9. The method of claim 1, before the step of executing a symbol detection model, further comprising the step of:
preprocessing the 2D file for denoising, thresholding and isolation of the floorplan portion of the 2D file and removal of extraneous text and figures.

10. The method of claim 1, wherein the 2D file is saved to a cloud storage service.

11. The method of claim 1, wherein a database file is generated based on the uploaded 2D file and the inputted default structural settings.

12. The method of claim 1, further comprising:
inputting default finish settings; and
applying finishes to the 3D file based on the inputted default finish settings.

13. The method of claim 1, further comprising:
converting the uploaded 2D file to PDF format.

14. The method of claim 7, wherein the step of post-processing of identified symbols comprises utilizing the circle Hough Transform to provide details on circular columns and doors present in the architectural floorplan.

15. A system for generating a three-dimensional (3D) file based on a two-dimensional (2D) architectural floorplan comprising:
a frontend having a graphical user interface, the frontend adapted to receive a 2D image of an architectural floorplan;
a cloud storage service in communication with the frontend; and
a backend in communication with the frontend and with the cloud storage device, the backend adapted to enqueue a plurality of worker instances, the plurality of worker instances comprising:
a symbol detection model trained to detect symbols present in architectural floorplans;
a segmentation model trained to identify segments present in architectural floorplans; and
a Blender software adapted to transform 2D outputs from the symbol detection model and segmentation model into a 3D file based on structural settings contained in a database file.

16. The system of claim 15, wherein the frontend is in communication with a 3D computer graphics engine, such that the 3D file can be viewed.

17. The system of claim 15, wherein the graphical user interface of the frontend is adapted to receive the structural settings.

18. The system of claim 15, the plurality of worker instances further comprising:
a vectorization worker instance wherein the identified segments are vectorized.

19. The system of claim 15, the plurality of worker instances further comprising:
a millwork detection worker instance, wherein detected symbols and identified segments are masked to yield millwork.

20. The system of claim 15, wherein the graphical user interface of the frontend is adapted to receive finish settings, wherein the finish settings are utilized by the Blender software to apply finishes to the 3D file.
